(19) United States
(12) Patent Application Publication
(10) Pub. No.: US 2025/0311317 A1
(43) Pub. Date: Oct. 2, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masataka INO, Oita Oita (JP)

(21) Appl. No.: 18/816,492

(22) Filed: Aug. 27, 2024

(30) Foreign Application Priority Data
Apr. 2, 2024 (JP) 2024-059657

(51) Int. Cl. H01L 29/06; H01L 29/04; H01L 29/423

(52) U.S. Cl. CPC H10D 62/102; H10D 62/405; H10D 64/514; H10D 64/518

(57) ABSTRACT

According to one embodiment, a semiconductor device includes first and second electrodes, first to third semiconductor regions, and a conductor. The conductor includes first and second gate electrode portions, a first wiring portion, and first and second connection portions. The first connection portion is connected between a first end portion of the first gate electrode portion and an end portion of the first wiring portion. The second connection portion is connected between a second end portion of the second gate electrode portion and the end portion of the first wiring portion. In the second direction, a position of the first wiring portion is between a position of the first gate electrode portion and a position of the second gate electrode portion. The first connection portion and the second connection portion have inclined surfaces that are inclined with respect to the second direction and the third direction.

### CROSS-REFERENCE TO RELATED APPLICATIONS

This application is based upon and claims the benefit of priority from Japanese Patent Application No. 2024-059657, filed on Apr. 2, 2024; the entire contents of which are incorporated herein by reference.

### FIELD

Embodiments of the present invention generally relate to a semiconductor device.

### BACKGROUND

Semiconductor devices such as metal oxide semiconductor field effect transistors (MOSFETs) are used for power conversion or other applications. There is a need for technology that can suppress the occurrence of breakdown in semiconductor devices.

### BRIEF DESCRIPTION OF THE DRAWINGS

FIG. 1 is a plan view illustrating a semiconductor device according to the embodiment;

FIG. 2 is an enlarged plan view of part II of FIG. 1;

FIG. 3 is III-III cross-section view of FIG. 2;

FIG. 4 is IV-IV cross-section view of FIG. 2;

FIG. 5 is V-V cross-section view of FIG. 2;

FIG. 6 is an enlarged plan view of a part of FIG. 2;

FIG. 7 is a cross-sectional view illustrating a manufacturing process of the semiconductor device according to the embodiment;

FIG. 8 is a plan view illustrating the manufacturing process of the semiconductor device according to the embodiment;

FIGS. 9A and 9B are cross-sectional views illustrating the manufacturing process of the semiconductor device according to the embodiment;

FIGS. 10A and 10B are cross-sectional views illustrating the manufacturing process of the semiconductor device according to the embodiment;

FIG. 11 is a plan view illustrating a part of a semiconductor device according to a reference example;

FIG. 12A is a plan view illustrating a manufacturing process of the semiconductor device according to the reference example, and FIG. 12B is a plan view illustrating the manufacturing process of the semiconductor device according to the embodiment;

FIG. 13 is a plan view illustrating a part of a semiconductor device according to a modification of the embodiment; and

FIG. 14 is XIV-XIV cross-section view of FIG. 13.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a conductor, and a second electrode. The first semiconductor region is provided on the first electrode. The first semiconductor region includes a first portion and a second portion located around the first portion along a plane. The plane is perpendicular to a first direction from the first electrode to the first semiconductor region. The second semiconductor region is provided on the first portion. The third semiconductor region is provided on the second semiconductor region. The conductor is provided on the first semiconductor region via an insulating layer. The conductor includes a first gate electrode portion, a second gate electrode portion, a first wiring portion, a first connection portion, and a second connection portion. The first gate electrode portion is located on the first portion. The first gate electrode portion faces the second semiconductor region in a second direction perpendicular to the first direction. The first gate electrode portion extends in a third direction perpendicular to the first direction and the second direction. The second gate electrode portion extends in the third direction. The second semiconductor region is positioned between the first gate electrode portion and the second gate electrode portion. The first wiring portion is located on the second portion and extending in the third direction. The first connection portion is connected between a first end portion in the third direction of the first gate electrode portion and an end portion in the third direction of the first wiring portion. The second connection portion is connected between a second end portion in the third direction of the second gate electrode portion and the end portion of the first wiring portion. A position in the second direction of the first wiring portion is between a position in the second direction of the first gate electrode portion and a position in the second direction of the second gate electrode portion. The first connection portion and the second connection portion have inclined surfaces that are inclined with respect to the second direction and the third direction. The second electrode is provided on the second semiconductor region and the third semiconductor region.

Various embodiments will be described hereinafter with reference to the accompanying drawings. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions. In the specification and drawings, components similar to those described or illustrated in a drawing therein above are marked with like reference numerals, and a detailed description is omitted as appropriate.

In the following descriptions and drawings, notations of n⁺, n⁻ and p⁺, p represent relative heights of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

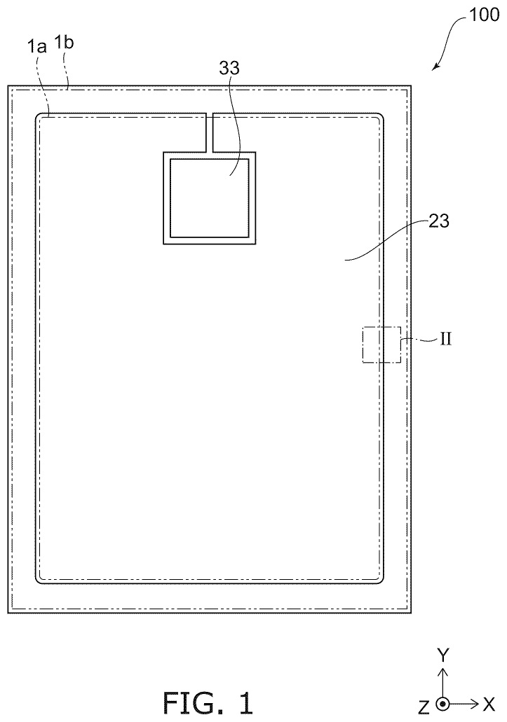

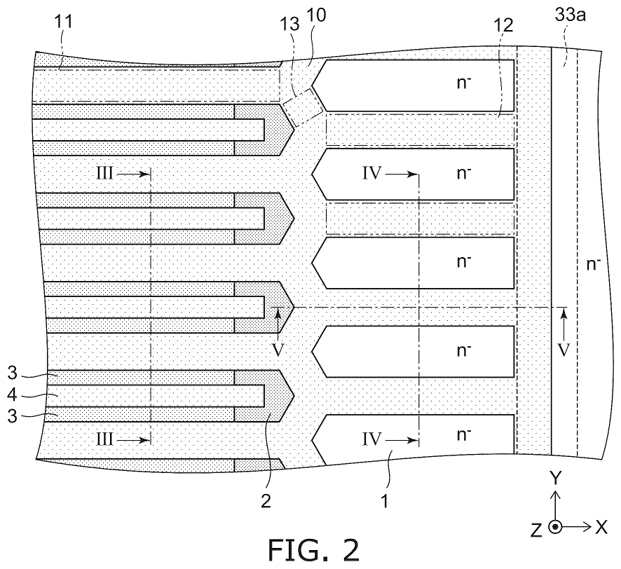

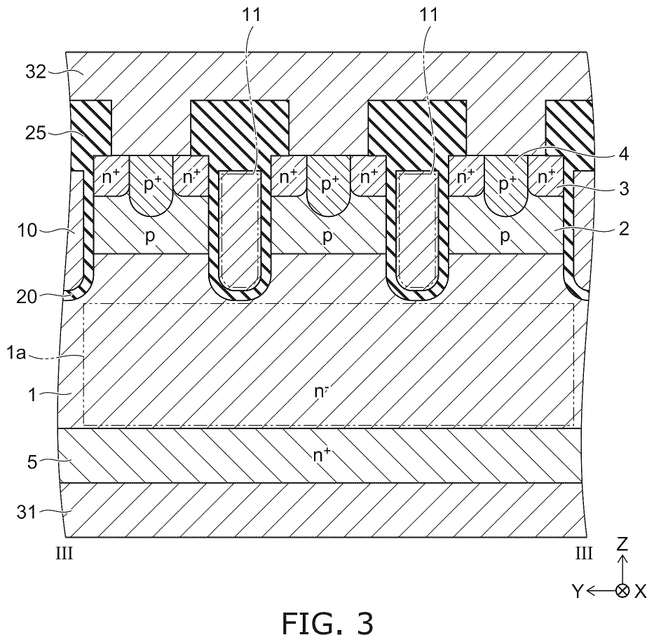

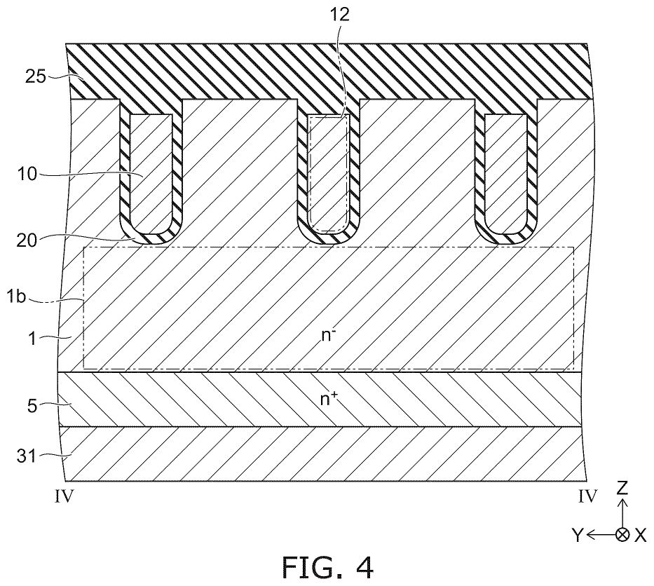

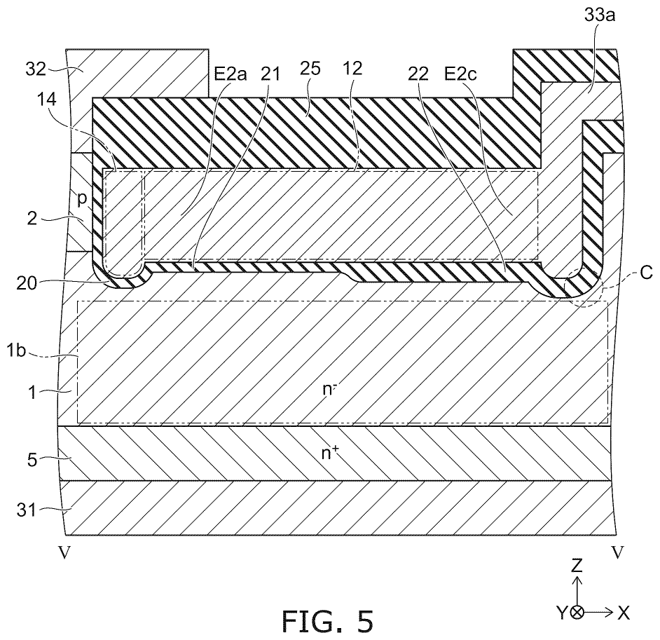

FIG. 1 is a plan view illustrating a semiconductor device according to the embodiment. FIG. 2 is an enlarged plan view of part II of FIG. 1. FIG. 3 is III-III cross-section view of FIG. 2. FIG. 4 is IV-IV cross-section view of FIG. 2. FIG. 5 is V-V cross-section view of FIG. 2.

The semiconductor device 100 according to the embodiment is a MOSFET. As shown in FIGS. 1 to 5, the semiconductor device 100 includes an n⁻-type (a first conductive type) drift region 1 (a first semiconductor region), a p-type (a second conductive type) base region 2 (a second semiconductor region), an n⁺-type source region 3 (a third semiconductor region), a p⁺-type semiconductor region 4, an n⁺-type drain region 5, a conductor 10, an insulating layer 20, an insulating layer 25, a drain electrode 31 (a first electrode), a source electrode 32 (a second electrode), a gate pad 33, and a wiring layer 33a. In FIG. 2, the insulating layer 20, the insulating layer 25, and the source electrode 32 are omitted, and the wiring layer 33a is depicted with a dashed line.

An XYZ orthogonal coordinate system is used in the description of the embodiments. The direction from the drain electrode 31 toward the n⁻-type drift region 1 is taken as a Z-direction (a first direction). Two mutually-orthogonal directions perpendicular to the Z-direction are taken as a Y-direction (a second direction) and an X-direction (a third direction). In the description, the direction from the drain electrode 31 toward the n⁻-type drift region 1 is called “up/upward/higher than”. The opposite direction is called “down/downward/below/lower than”. These directions are based on the relative positional relationship between the drain electrode 31 and the n⁻-type drift region 1 and are independent of the direction of gravity.

As shown in FIG. 1, the source electrode 32 and the gate pad 33 are provided on the upper surface of the semiconductor device 100. The source electrode 32 and the gate pad 33 are separated from each other and electrically isolated.

As shown in FIG. 2, the conductor 10 is provided below the source electrode 32 and the gate pad 33. The conductor 10 is electrically isolated from the source electrode 32. The conductor 10 is electrically connected to the gate pad 33 via the wiring layer 33a provided on the outer periphery of the semiconductor device 100.

As shown in FIGS. 3 and 4, the drain electrode 31 is provided on the lower surface of the semiconductor device 100. The n⁺-type drain region 5 is provided on the drain electrode 31 and electrically connected to the drain electrode 31. The n⁻-type drift region 1 is provided on the n⁺-type drain region 5. The n⁻-type drift region 1 is electrically connected to the drain electrode 31 via the n⁺-type drain region 5. The n-type impurity concentration in the n⁻-type drift region 1 is lower than the n-type impurity concentration in the n⁺-type drain region 5.

As shown in FIGS. 1 and 3 to 5, the n⁻-type drift region 1 includes the first portion 1a and the second portion 1b. The second portion 1b is located around the first portion 1a in the X-Y plane. The first portion 1a is located in a cell region. The cell region is the region through which a current mainly flows during the operation of the semiconductor device 100. The second portion 1b is located in a termination region. The termination region is the region where the depletion layer spreads toward the outer periphery of the semiconductor device 100 when the semiconductor device 100 is withstanding a voltage.

As shown in FIG. 3, the p-type base region 2 is provided on the first portion 1a. The n⁺-type source region 3 and the p⁺-type semiconductor region 4 are provided on the p-type base region 2. The p-type impurity concentration in the p⁺-type semiconductor region 4 is greater than the p-type impurity concentration in the p-type base region 2.

The conductor 10 is provided on the n⁻-type drift region 1 via the insulating layer 20. As shown in FIG. 2, the conductor 10 includes multiple gate electrode portions 11, multiple wiring portions 12, and multiple connection portions 13.

As shown in FIG. 3, the multiple gate electrode portions 11 are provided on the first portion 1a. Each gate electrode portion 11 extends in the X-direction. The gate electrode portion 11 faces the p-type base region 2 via the insulating layer 20 in the Y-direction. The multiple p-type base regions 2 and the multiple gate electrode portions 11 are alternately arranged in the Y-direction.

As shown in FIG. 4, the multiple wiring portions 12 are provided on the second portion 1b. Each wiring portion 12 extends in the X-direction. In the Y-direction, parts of the n⁻-type drift region 1 and the multiple wiring portions 12 are alternately arranged.

As shown in FIG. 2, the connection portion 13 is connected between the gate electrode portion 11 and the wiring portion 12, and electrically connects one end in the X-direction of the gate electrode portion 11 and one end in the X-direction of the wiring portion 12. The connection portion 13 has a surface inclined with respect to the X-direction and the Y-direction.

The other ends in the X-direction of the wiring portions 12 are connected to each other in the Y-direction and are connected to the wiring layer 33a.

The position in the Y-direction of the wiring portion 12 is between the position in the Y-direction of one gate electrode portion 11 and the position in the Y-direction of another one gate electrode portion 11 adjacent thereto. When viewed from the X-direction, the multiple gate electrode portions 11 and the multiple wiring portions 12 are alternately arranged in the Y-direction.

As shown in FIG. 3, the source electrode 32 is provided on the p-type base region 2, the n⁺-type source region 3, and the p⁺-type semiconductor region 4. The source electrode 32 is electrically connected to the p-type base region 2, the n⁺-type source region 3, and the p⁺-type semiconductor region 4. The insulating layer 25 is provided between the conductor 10 and the source electrode 32. The conductor 10 and the source electrode 32 are electrically isolated by the insulating layer 25.

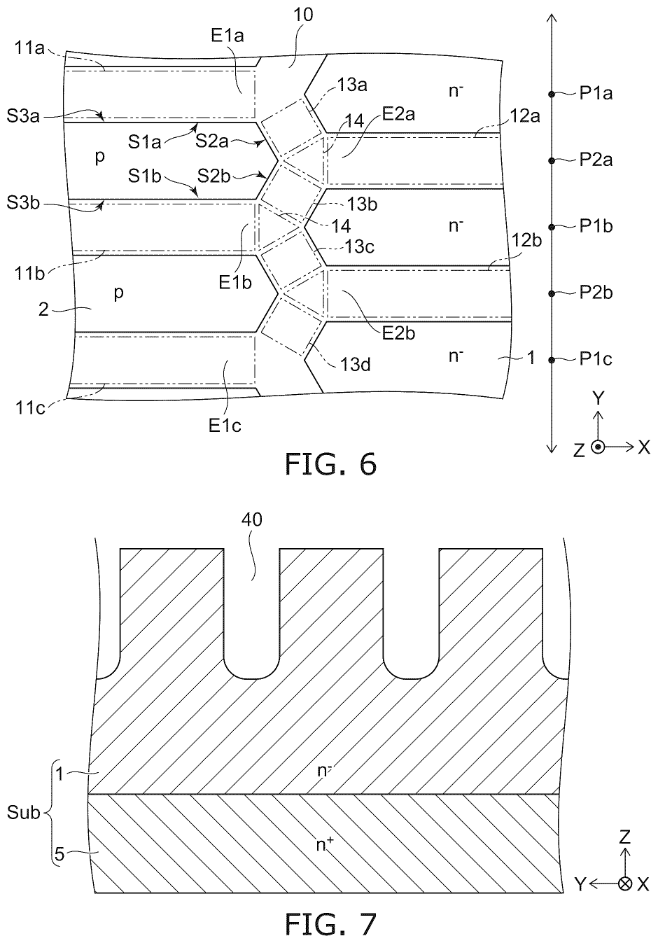

FIG. 6 is an enlarged plan view of a part of FIG. 2.

As a specific example of the conductor 10, the multiple gate electrode portions 11 include a first gate electrode portion 11a and a second gate electrode portion 11b, as shown in FIG. 6. The multiple wiring portions 12 include a first wiring portion 12a. The first gate electrode portion 11a and the second gate electrode portion 11b are adjacent to each other in the Y-direction. The position P2a in the Y-direction of the first wiring portion 12a is between the position P1a in the Y-direction of the first gate electrode portion 11a and the position P1b in the Y-direction of the second gate electrode portion 11b.

The first gate electrode portion 11a includes a first end portion E1a in the X-direction. The second gate electrode portion 11b includes a second end portion E1b in the X-direction. The first wiring portion 12a includes an end portion E2a in the X-direction. The multiple connection portions 13 include a first connection portion 13a and a second connection portion 13b. The first connection portion 13a is connected between the first end portion E1a of the first gate electrode portion 11a and the end portion E2a of the first wiring portion 12a. The second connection portion 13b is connected between the second end portion E1b of the second gate electrode portion 11b and the end portion E2a of the first wiring portion 12a.

The first gate electrode portion 11a has a side surface S1a parallel to the X-direction. The second gate electrode portion 11b has a side surface S1b parallel to the X-direction. The first connection portion 13a has a first inclined surface S2a inclined with respect to the X-direction and the Y-direction. The second connection portion 13b has a second inclined surface S2b inclined with respect to the X-direction and the Y-direction. The first inclined surface S2a is continuous with the side surface S1a. The second inclined surface S2b is continuous with the first inclined surface S2a. The side surface S1b is continuous with the second inclined surface S2b.

There are intermediate portions 14 between the gate electrode portion 11 and the connection portion 13, and between the wiring portion 12 and the connection portion 13, respectively. For example, as shown in FIG. 5, the lower end of the intermediate portion 14 is positioned lower than the lower end of the wiring portion 12. The position in the Z-direction of the lower end of the gate electrode portion 11 and the position in the Z-direction of the lower end of the connection portion 13 are substantially the same as the position in the Z-direction of the lower end of the wiring portion 12. Therefore, the lower end of the intermediate portion 14 is positioned lower than the lower end of the gate electrode portion 11 and the lower end of the connection portion 13.

As shown in FIG. 6, the multiple gate electrode portions 11 may further include a third gate electrode portion 11c. The multiple wiring portions 12 may further include a second wiring portion 12b. The multiple connection portions 13 may further include a third connection portion 13c and a fourth connection portion 13d. The second gate electrode portion 11b and the third gate electrode portion 11c are adjacent to each other in the Y-direction. The position P2b in the Y-direction of the second wiring portion 12b is between the position P1b in the Y-direction of the second gate electrode portion 11b and the position Plc in the Y-direction of the third gate electrode portion 11c.

The third gate electrode portion 11c includes a third end portion E1c in the X-direction. The second wiring portion 12b includes an end portion E2b in the X-direction. The third connection portion 13c is connected between the second end portion E1b of the second gate electrode portion 11b and the end portion E2b of the second wiring portion 12b. The fourth connection portion 13d is connected between the third end portion E1c of the third gate electrode portion 11c and the end portion E2b of the second wiring portion 12b. The third connection portion 13c and the fourth connection portion 13d have inclined surfaces that are inclined with respect to the X-direction and the Y-direction.

As shown in FIGS. 2 and 6, at the height (the position in the Z-direction) where the p-type base region 2 is provided, the n⁻-type drift region 1 and the p-type base region 2 are separated by the connection portion 13 and the intermediate portion 14. By partitioning the range where the p-type base region 2 is provided with the conductor 10, the variation in the range of the p-type base region 2 can be suppressed compared to the case where the p-type base region 2 is not partitioned. The variation in the breakdown voltage of the semiconductor device 100 due to the variation in the range of the p-type base region 2 can be suppressed.

The operation of the semiconductor device 100 will now be described.

A voltage exceeding the threshold is applied to the conductor 10 in a state where a positive voltage with respect to the source electrode 32 is applied to the drain electrode 31. As a result, a channel (an inversion layer) is formed in the p-type base region 2 opposite the gate electrode portion 11. Electrons flow from the source electrode 32 to the n⁻-type drift region 1 through the channel; and the semiconductor device 100 is turned on. Thereafter, when the voltage applied to the conductor 10 becomes lower than the threshold, the channel in the p-type base region 2 disappears; and the semiconductor device 100 is turned off.

An example of the material of each component will now be described.

The n⁻-type drift region 1, the p-type base region 2, the n⁺-type source region 3, the p⁺-type semiconductor region 4, and the n⁺-type drain region 5 include silicon, silicon carbide, gallium nitride, or gallium arsenide as a semiconductor material. When silicon is used as the semiconductor material, arsenic, phosphorus, or antimony can be used as an n-type impurity. As a p-type impurity, boron can be used. The conductor 10 and the wiring layer 33a include a conductive material such as polysilicon. Impurities may be added to the conductor 10. The insulating layer 20 and the insulating layer 25 include an insulating material such as silicon oxide, silicon nitride, or silicon oxynitride. The drain electrode 31, the source electrode 32, and the gate pad 33 include a metal such as titanium, gold, or aluminum.

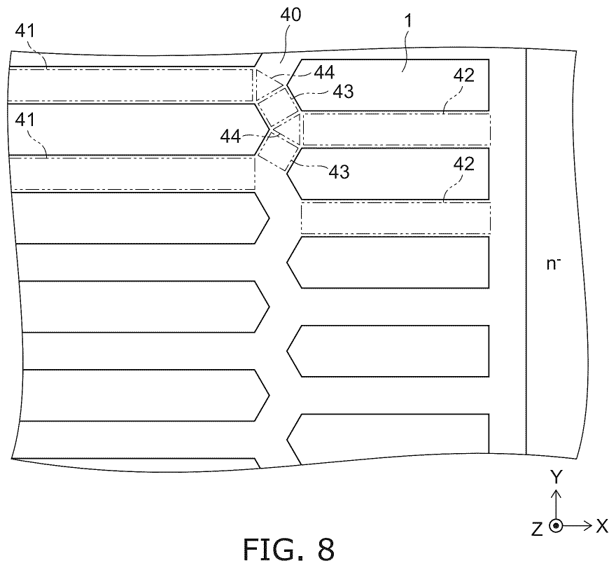

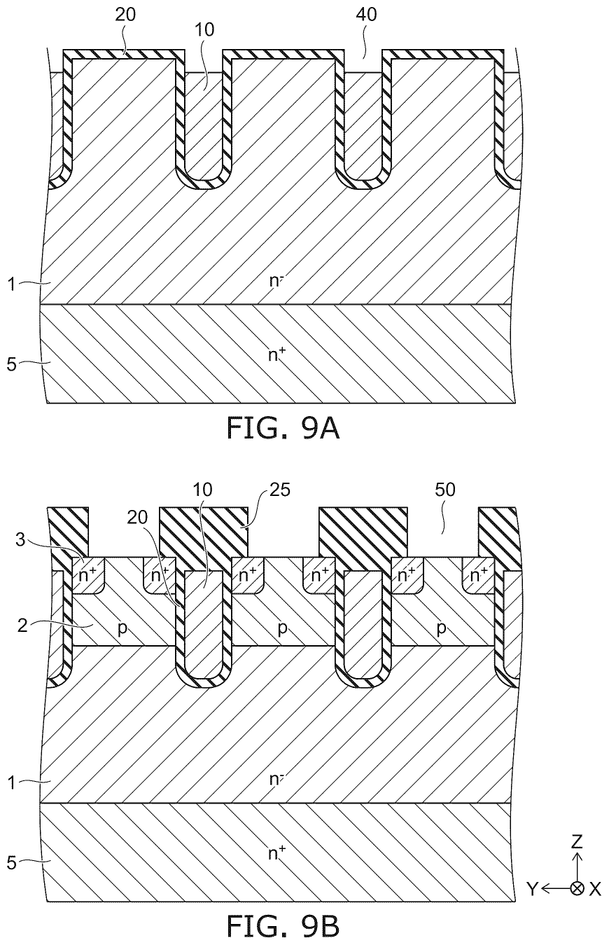

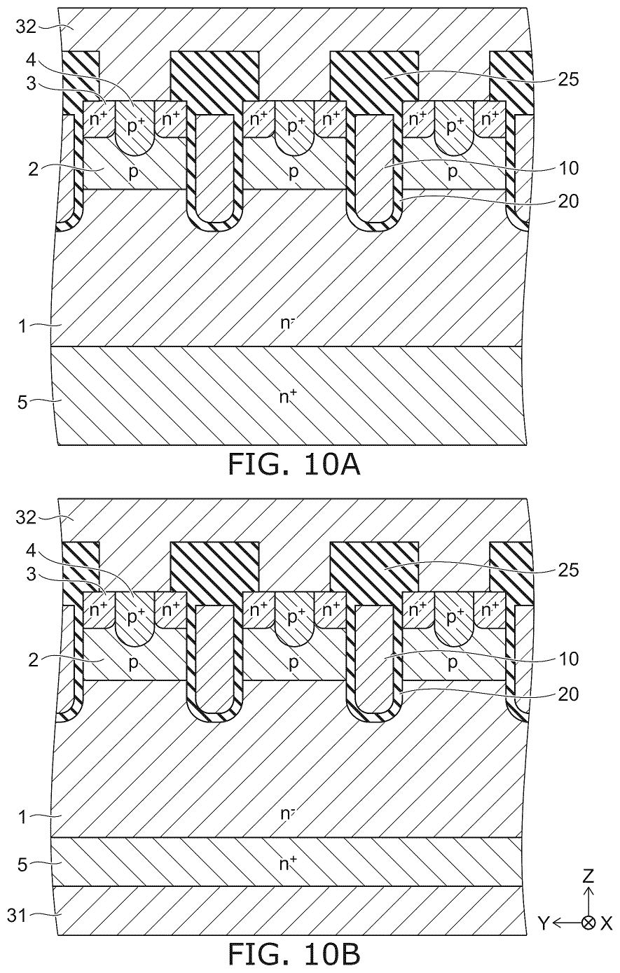

FIG. 7, FIGS. 9A and 9B, and FIGS. 10A and 10B are cross-sectional views illustrating a manufacturing process of the semiconductor device according to the embodiment. FIG. 8 is a plan view illustrating the manufacturing process of the semiconductor device according to the embodiment.

First, a semiconductor substrate Sub including the n⁻-type drift region 1 and the n⁺-type drain region 5 is prepared. An opening 40 is formed on the upper surface of the n⁻-type drift region 1 by reactive ion etching (RIE), as shown in FIG. 7.

As shown in FIG. 8, the opening 40 includes multiple first trenches 41, multiple second trenches 42, multiple third trenches 43, and multiple intermediate portions 44. The first trenches 41 are located on the first portion 1a. The second trenches 42 are located on the second portion 1b. The third trench 43 is located between an end portion in the Y-direction of the first trench 41 and an end portion in the Y-direction of the second trench 42. The side surface of the third trench 43 is inclined with respect to the X-direction and the Y-direction. The intermediate portion 44 is located between the first trench 41 and the third trench 43, or between the second trench 42 and the third trench 43.

The insulating layer 20 is formed along the upper surface of the n⁻-type drift region 1 and the inner surface of the opening 40 by thermal oxidation. A conductive layer is formed on the insulating layer 20 to fill the opening 40. The upper surface of the conductive layer is caused to be retreated by wet etching or chemical dry etching (CDE), forming the conductor 10 inside the opening 40, as shown in FIG. 9A.

The conductor 10 formed inside the first trench 41 corresponds to the gate electrode portion 11. The conductor 10 formed inside the second trench 42 corresponds to the wiring portion 12. The conductor 10 formed inside the third trench 43 corresponds to the connection portion 13. The conductor 10 formed inside the intermediate portion 44 corresponds to the intermediate portion 14.

P-type impurities and n-type impurities are sequentially ion-implanted into the region between the first trenches 41 to form the p-type base region 2 and the n⁺-type source region 3. The insulating layer 25 is formed on the conductor 10. As shown in FIG. 9B, a part of the insulating layer 20 and a part of the insulating layer 25 are removed to form an opening 50.

P-type impurities are ion-implanted, through the opening 50, into the region between the n⁺-type source regions 3 to form the p⁺-type semiconductor region 4. As shown in FIG. 10A, the source electrode 32 is formed by sputtering to fill the opening 50. The lower surface of the n⁺-type drain region 5 is ground until the n⁺-type drain region 5 reaches a predetermined thickness. As shown in FIG. 10B, the drain electrode 31 is formed on the ground lower surface of the n⁺-type drain region 5 by sputtering. As described above, the semiconductor device 100 according to the embodiment is manufactured.

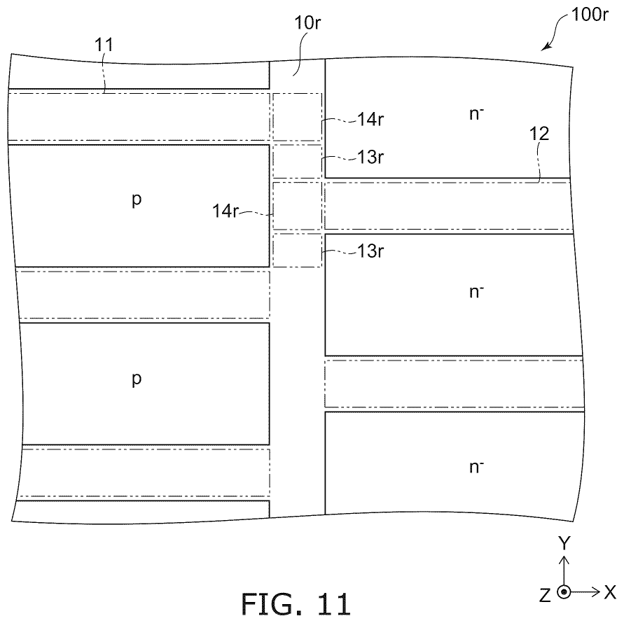

FIG. 11 is a plan view illustrating a part of a semiconductor device according to a reference example.

In the semiconductor device 100r shown in FIG. 11, the conductor 10r includes a gate electrode portion 11, a wiring portion 12, and a connection portion 13r. The connection portion 13r is connected between the gate electrode portion 11 and the wiring portion 12. The orientation of the connection portion 13r is different from the orientation of the connection portion 13 in the semiconductor device 100 according to the embodiment. The side surfaces of the connection portion 13r are perpendicular to the X-direction and parallel to the Y-direction. Additionally, the conductor 10r includes an intermediate portion 14r. The intermediate portion 14r is located between the gate electrode portion 11 and the connection portion 13r, or between the wiring portion 12 and the connection portion 13r.

Advantages of the embodiment will now be described.

In the manufacture of the semiconductor device 100, when the conductor 10 is formed, the opening 40 is formed as shown in FIGS. 7 and 8. Dry etching is used to form the opening 40 in the semiconductor layer. In the dry etching, plasma of gas that has reactivity with a semiconductor material is used. The semiconductor material is removed by the reaction between the radicals of the gas and the semiconductor material; and the opening 40 is formed. At this time, in the portion of opening 40 that has a wider width, radicals are more likely to enter inside the opening compared to the portion of opening 40 that has a narrower width, and etching is more likely to proceed.

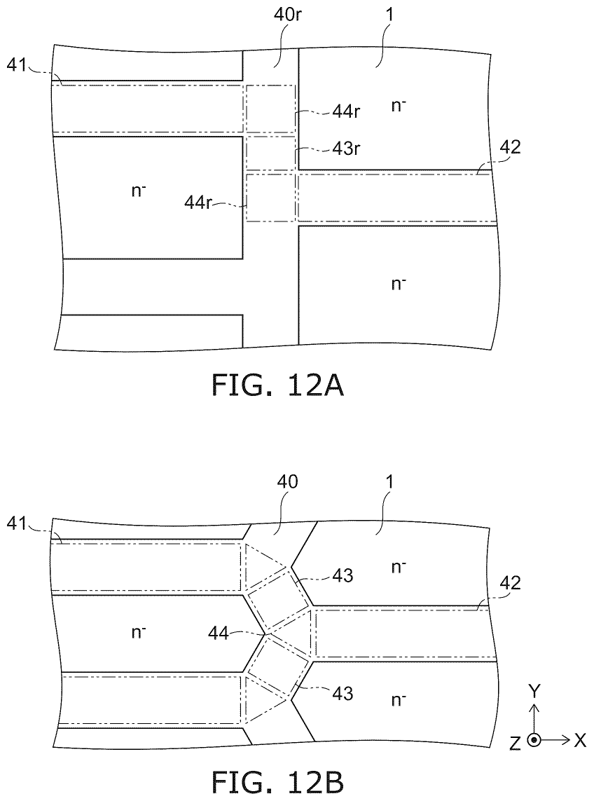

FIG. 12A is a plan view illustrating a manufacturing process of the semiconductor device according to the reference example. FIG. 12B is a plan view illustrating the manufacturing process of the semiconductor device according to the embodiment.

When the semiconductor device 100r is manufactured, as shown in FIG. 12A, an opening 40r for producing the conductor 10r is formed. The opening 40r includes a first trench 41, a second trench 42, a third trench 43r, and an intermediate portion 44r.

The third trench 43r is located between an end portion in the Y-direction of the first trench 41 and an end portion in the Y-direction of the second trench 42. The side surfaces of the third trench 43r are perpendicular to the X-direction and parallel to the Y-direction. The intermediate portion 44r is located between the first trench 41 and the third trench 43r, or between the second trench 42 and the third trench 43r. A conductive layer including polysilicon is embedded in the opening 40r to form the conductor 10r. At this time, a part of the conductor 10r is located inside the intermediate portion 44r. The part of the conductor 10r corresponds to the intermediate portion 14r.

As shown in FIG. 11, the width of the intermediate portion 14r is wider than the width of each of the gate electrode portion 11, the wiring portion 12, and the connection portion 13r. Therefore, as shown in FIG. 12, the width of the intermediate portion 44r, where the intermediate portion 14r is formed, is also wider than the width of each of the gate electrode portion 11, the wiring portion 12, and the connection portion 13r. Thus, etching proceeds more easily in the intermediate portion 44r than in the first trench 41, the second trench 42, and the third trench 43r. The lower end of the intermediate portion 44r is formed deeper than the lower end of each of the first trench 41, the second trench 42, and the third trench 43r. As a result, in the conductor 10r formed inside the opening 40r, the lower end of the intermediate portion 14r is positioned lower than the lower ends of other portions such as the gate electrode portion 11, the wiring portion 12, and the connection portion 13r. In other words, the lower end of the intermediate portion 14r protrudes downward with respect to the lower ends of the other portions.

The further the lower end of the intermediate portion 14r protrudes downward, the more likely an electric field concentration is to occur in the vicinity of the lower end of the intermediate portion 14r. In other words, the electric field strength in the vicinity of the lower end of the intermediate portion 14r is greater than the electric field strength in the vicinity of the lower ends of the other portions. There is a possibility that dielectric breakdown of the insulating layer 20 occurs in the vicinity of the lower end of the intermediate portion 14r, causing the semiconductor device 100r to breakdown.

In the semiconductor device 100, the connection portion 13 has an inclined surface that is inclined with respect to the X-direction and the Y-direction. In such a case, when the conductor 10 is formed, the side surfaces of the third trench 43 are also inclined with respect to the X-direction and the Y-direction, as shown in FIG. 12B.

In the example shown in FIG. 12A, the first trench 41 or the second trench 42 intersects the third trench 43r from a direction orthogonal to the third trench 43r. In the example shown in FIG. 12B, the first trench 41 or the second trench 42 intersects the third trench 43 from a direction not orthogonal to the third trench 43. When the structure shown in FIG. 12B is used, the area of the intermediate portion 44 located between them is smaller than the area of the intermediate portion 44r shown in FIG. 12A. Therefore, in manufacturing the semiconductor device 100, although etching proceeds more easily in the intermediate portion 44 than in the first trench 41, the second trench 42, and the third trench 43, the amount of etching in the intermediate portion 44 can be reduced compared to amount of etching in the intermediate portion 44r. In the conductor 10, the protrusion amount of the lower end of the intermediate portion 14 with respect to the other portions can be suppressed, and the electric field concentration in the vicinity of the lower end of the intermediate portion 14 can be suppressed. The electric field strength in the vicinity of the lower end of the intermediate portion 14 can be reduced, and the occurrence of breakdown in the semiconductor device 100 can be suppressed.

As shown in FIG. 6, the first inclined surface S2a of the first connection portion 13a is not parallel to the second inclined surface S2b of the second connection portion 13b. Preferably, the angle between the first inclined surface S2a and the second inclined surface S2b is greater than 90 degrees and less than 150 degrees. Within this angle range, the area in the X-Y plane of the intermediate portion 14 can be effectively reduced. In other words, the electric field strength in the vicinity of the lower end of the intermediate portion 14 can be effectively reduced.

As shown in FIG. 5, the insulating layer 20 may include a first insulating region 21 and a second insulating region 22. The first insulating region 21 is located between the end portion E2a of the first wiring portion 12a and the second portion 1b. The second insulating region 22 is located between the other end portion E2b in the Y-direction of the first wiring portion 12a and the second portion 1b. The thickness of the second insulating region 22 is larger than the thickness of the first insulating region 21.

The conductor 10 includes an outer peripheral portion positioned outside the wiring portion 12. The outer peripheral portion is raised higher than the semiconductor region and connected to the wiring layer 33a. In the raised portion, a corner portion C is formed as shown in FIG. 5. In the corner portion C, electric field concentration is more likely to occur compared to other portions. By making the second insulating region 22 thicker than the first insulating region 21, the electric field concentration in the vicinity of the corner portion C can be suppressed, and the occurrence of breakdown in the semiconductor device 100 can be further suppressed.

As shown in FIG. 6, the p-type base region 2 has a first surface S3a and a second surface S3b. The first surface S3a faces the first gate electrode portion 11a in the Y-direction. The second surface S3b faces the second gate electrode portion 11b in the Y-direction. The crystal orientation of the first surface S3a and the crystal orientation of the second surface S3b are preferably {100} plane or {110} plane. This is because when the semiconductor device 100 is in the on-state, the mobility of electrons in the channel can be increased, and the on-resistance of the semiconductor device 100 can be reduced. In such a case, the crystal orientation of the first inclined surface S2a and the crystal orientation of the second inclined surface S2b are inclined with respect to the {100} plane or {110} plane.

### (Modification)

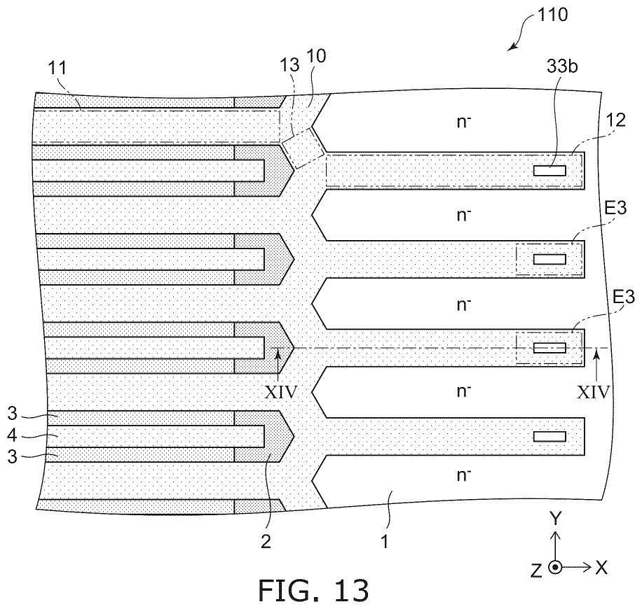

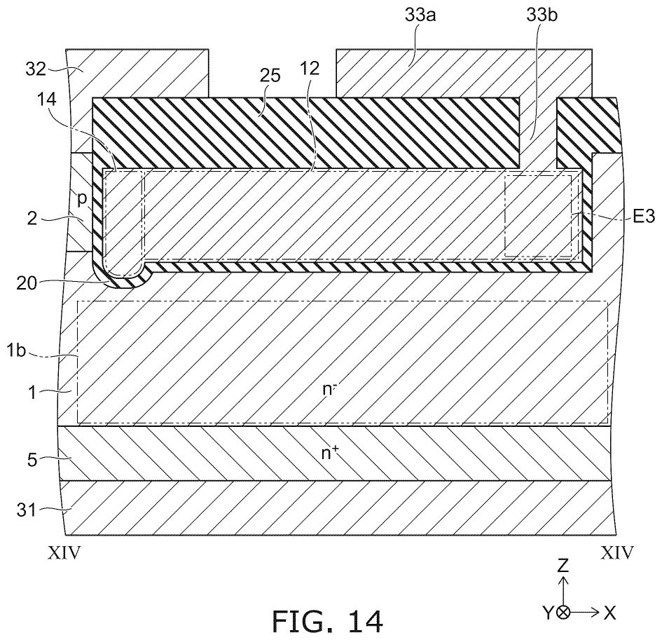

FIG. 13 is a plan view illustrating a part of a semiconductor device according to a modification of the embodiment. FIG. 14 is XIV-XIV cross-section view of FIG. 13. In FIG. 13, the insulating layer 20, the insulating layer 25, and the source electrode 32 are omitted.

In the semiconductor device 110 according to the modification, as shown in FIG. 13, a contact plug 33b is provided on the wiring portion 12. As shown in FIG. 14, the wiring portion 12 is electrically connected to the wiring layer 33a via the contact plug 33b. The insulating layer 25 is provided between the wiring portion 12 and the wiring layer 33a.

In the semiconductor device 100, as shown in FIG. 2, the ends in the X-direction of the wiring portion 12 are connected to each other. This is to simultaneously form the wiring layer 33a and the conductor 10. On the other hand, in the semiconductor device 110, the end portions E3 in the X-direction of the wiring portion 12 are separated from each other in the Y-direction, as shown in FIG. 13. According to this structure, when forming an opening for the wiring portion 12, the widening at the end of the opening can be suppressed. This allows the suppression of the localized progression of etching when forming the opening. As a result, as shown in FIG. 14, the protrusion amount of the lower end of the end portion E3 can be suppressed. The electric field strength in the vicinity of the lower end of the end portion E3 can be reduced, and the occurrence of breakdown in the semiconductor device 110 can be suppressed.

In addition, according to the semiconductor device 110, the electric field strength in the vicinity of the lower end of the end portion E3 can be reduced. Therefore, the relatively thick second insulating region 22 shown in FIG. 5 becomes unnecessary.

Embodiments of the present invention include the following features.

### (Feature 1)

A semiconductor device comprising:
a first electrode;
a first semiconductor region of a first conductivity type provided on the first electrode, the first semiconductor region including a first portion and a second portion located around the first portion along a plane that is perpendicular to a first direction from the first electrode to the first semiconductor region;
a second semiconductor region of a second conductivity type provided on the first portion;
a third semiconductor region of the first conductivity type provided on the second semiconductor region;
a conductor provided on the first semiconductor region via an insulating layer, the conductor including
   a first gate electrode portion located on the first portion, facing the second semiconductor region in a second direction perpendicular to the first direction, and extending in a third direction perpendicular to the first direction and the second direction,
   a second gate electrode portion extending in the third direction, the second semiconductor region being positioned between the first gate electrode portion and the second gate electrode portion,
   a first wiring portion located on the second portion and extending in the third direction,
   a first connection portion connected between a first end portion in the third direction of the first gate electrode portion and an end portion in the third direction of the first wiring portion, and
   a second connection portion connected between a second end portion in the third direction of the second gate electrode portion and the end portion of the first wiring portion,
a position in the second direction of the first wiring portion being between a position in the second direction of the first gate electrode portion and a position in the second direction of the second gate electrode portion, the first connection portion and the second connection portion having inclined surfaces that are inclined with respect to the second direction and the third direction; and
a second electrode provided on the second semiconductor region and the third semiconductor region.

### (Feature 2)

The semiconductor device according to feature 1, wherein
the conductor includes an intermediate portion located between the first connection portion, the second connection portion, and the end portion of the first wiring portion, and
a lower end of the intermediate portion is positioned lower than a lower end of the first wiring portion.

### (Feature 3)

The semiconductor device according to feature 1 or 2, wherein
the first connection portion has a first inclined surface that is inclined with respect to the second direction and the third direction,
the second connection portion has a second inclined surface that is inclined with respect to the second direction and the third direction, the second inclined surface is continuous with the first inclined surface, and
an angle between the first inclined surface and the second inclined surface is greater than 90 degrees and less than 150 degrees.

### (Feature 4)

The semiconductor device according to any one of features 1 to 3, wherein
the insulating layer includes
   a first insulating region located between the end portion of the first wiring portion and the second portion, and
   a second insulating region located between another end portion in the third direction of the first wiring portion and the second portion, and
a thickness of the second insulating region is greater than a thickness of the first insulating region.

### (Feature 5)

The semiconductor device according to any one of features 1 to 4, wherein
a length in the second direction of the first wiring portion is greater than a length in the second direction of the first gate electrode portion and greater than a length in the second direction of the second gate electrode portion.

### (Feature 6)

The semiconductor device according to any one of features 1 to 5, wherein
the second semiconductor region has a first surface facing the first gate electrode portion in the second direction,
a crystal orientation of the first surface is {100} plane or {110} plane, and
a crystal orientation of each of the inclined surfaces is inclined with respect to the {100} plane and the {110} plane.

### (Feature 7)

The semiconductor device according to any one of features 1 to 6, wherein
the conductor further includes
   a third gate electrode portion extending in the third direction, another second semiconductor region being located between the second gate electrode portion and the third gate electrode portion,
   a second wiring portion located on the second portion,
   a third connection portion located between the second end portion and an end portion in the third direction of the second wiring portion, and
   a fourth connection portion located between a third end portion in the third direction of the third gate electrode portion and the end portion of the second wiring portion,
a position in the second direction of the second wiring portion is between a position in the second direction of the second gate electrode portion and a position in the second direction of the third gate electrode portion, and
the third connection portion and the fourth connection portion have inclined surfaces that are inclined with respect to the second direction and the third direction.

### (Feature 8)

The semiconductor device according to any one of features 1 to 7, wherein
a plurality of gate electrode portions including the first gate electrode portion and the second gate electrode portion are arranged in the second direction on the first portion, and
a plurality of wiring portions including the first wiring portion are arranged in the second direction on the second portion.

### (Feature 9)

The semiconductor device according to feature 8, wherein
when viewed from the third direction, the plurality of gate electrode portions and the plurality of wiring portions are alternately arranged in the second direction.

It is possible to confirm the relative levels of the impurity concentrations between the semiconductor regions in the embodiments described above, for example, using a scanning capacitance microscope (SCM). The carrier concentrations in the semiconductor regions may be considered to be equal to the activated impurity concentrations in the semiconductor regions. Accordingly, the relative levels of the carrier concentrations in the semiconductor regions can be confirmed using SCM. It is possible to measure the impurity concentrations in the semiconductor regions, for example, using a secondary ion mass spectrometer (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a first semiconductor region of a first conductivity type provided on the first electrode, the first semiconductor region including a first portion and a second portion located around the first portion along a plane that is perpendicular to a first direction from the first electrode to the first semiconductor region;
a second semiconductor region of a second conductivity type provided on the first portion;
a third semiconductor region of the first conductivity type provided on the second semiconductor region;
a conductor provided on the first semiconductor region via an insulating layer, the conductor including
a first gate electrode portion located on the first portion, facing the second semiconductor region in a second direction perpendicular to the first direction, and extending in a third direction perpendicular to the first direction and the second direction,
a second gate electrode portion extending in the third direction, the second semiconductor region being positioned between the first gate electrode portion and the second gate electrode portion,
a first wiring portion located on the second portion and extending in the third direction,
a first connection portion connected between a first end portion in the third direction of the first gate electrode portion and an end portion in the third direction of the first wiring portion, and
a second connection portion connected between a second end portion in the third direction of the second gate electrode portion and the end portion of the first wiring portion,
a position in the second direction of the first wiring portion being between a position in the second direction of the first gate electrode portion and a position in the second direction of the second gate electrode portion, the first connection portion and the second connection portion having inclined surfaces that are inclined with respect to the second direction and the third direction; and
a second electrode provided on the second semiconductor region and the third semiconductor region.

2. The semiconductor device according to claim 1, wherein
the conductor includes an intermediate portion located between the first connection portion, the second connection portion, and the end portion of the first wiring portion, and
a lower end of the intermediate portion is positioned lower than a lower end of the first wiring portion.

3. The semiconductor device according to claim 1, wherein
the first connection portion has a first inclined surface that is inclined with respect to the second direction and the third direction,
the second connection portion has a second inclined surface that is inclined with respect to the second direction and the third direction, the second inclined surface is continuous with the first inclined surface, and
an angle between the first inclined surface and the second inclined surface is greater than 90 degrees and less than 150 degrees.

4. The semiconductor device according to claim 1, wherein
the insulating layer includes
a first insulating region located between the end portion of the first wiring portion and the second portion, and
a second insulating region located between another end portion in the third direction of the first wiring portion and the second portion, and
a thickness of the second insulating region is greater than a thickness of the first insulating region.

5. The semiconductor device according to claim 1, wherein
a length in the second direction of the first wiring portion is greater than a length in the second direction of the first gate electrode portion and greater than a length in the second direction of the second gate electrode portion.

6. The semiconductor device according to claim 1, wherein
the second semiconductor region has a first surface facing the first gate electrode portion in the second direction,
a crystal orientation of the first surface is {100} plane or {110} plane, and
a crystal orientation of each of the inclined surfaces are inclined with respect to the {100} plane and the {110} plane.

7. The semiconductor device according to claim 1, wherein
the conductor further includes
a third gate electrode portion extending in the third direction, another second semiconductor region being located between the second gate electrode portion and the third gate electrode portion,
a second wiring portion located on the second portion,
a third connection portion located between the second end portion and an end portion in the third direction of the second wiring portion, and
a fourth connection portion located between a third end portion in the third direction of the third gate electrode portion and the end portion of the second wiring portion,
a position in the second direction of the second wiring portion is between a position in the second direction of the second gate electrode portion and a position in the second direction of the third gate electrode portion, and
the third connection portion and the fourth connection portion have inclined surfaces that are inclined with respect to the second direction and the third direction.

8. The semiconductor device according to claim 1, wherein
a plurality of gate electrode portions including the first gate electrode portion and the second gate electrode portion are arranged in the second direction on the first portion, and
a plurality of wiring portions including the first wiring portion are arranged in the second direction on the second portion.

9. The semiconductor device according to claim 8, wherein
when viewed from the third direction, the plurality of gate electrode portions and the plurality of wiring portions are alternately arranged in the second direction.
